(19) United States
(12) Patent Application Publication
(10) Pub. No.: US 2019/0198423 A1
(43) Pub. Date: Jun. 27, 2019

(54) DEVICE MODULE EMBEDDED WITH SWITCH CHIP AND MANUFACTURING METHOD THEREOF

(71) Applicant: RAYBEN TECHNOLOGIES (ZHUHAI) LIMITED, Zhuhai (CN)

(72) Inventors: Wai Kin Raymond LAM, Zhuhai (CN); Ho Wai Derek LEUNG, Zhuhai (CN); Aibing CHEN, Zhuhai (CN); Weidong GAO, Zhuhai (CN)

(73) Assignee: RAYBEN TECHNOLOGIES (ZHUHAI) LIMITED, Zhuhai (CN)

(21) Appl. No.: 15/955,722

(22) Filed: Apr. 18, 2018

(30) Foreign Application Priority Data
Dec. 21, 2017 (CN) 201711391103.5

(51) Int. Cl. H01L 23/373; H01L 23/00; H01L 23/498; H01L 21/48

(52) U.S. Cl. CPC H01L 23/3737; H01L 24/81; H01L 21/4846; H01L 23/49827; H01L 24/17

(57) ABSTRACT

The present invention provides a device module embedded with switch chip and a manufacturing method thereof, the device module includes: a double-sided circuit board, the first surface of the double-sided circuit board is provided with first pads, and the second surface opposite to the first surface is provided with second pads; a heat dissipation substrate embedded with an electric insulation heat dissipation body and arranged at a side of the first surface of the double-sided circuit board; a switch chip embedded in a heat dissipation substrate, the pins of the switch chip are soldered to the first pads, and the other side of the switch chip opposite to the side of the pins is thermally connected to the electric insulation heat dissipation body; energy storage device, whose pins are soldered to the second pads.

### CROSS REFERENCE TO RELATED APPLICATIONS

This application is based upon and claims priority to Chinese Patent Application No. CN 201711391103.5, filed on Dec. 21, 2017, the entire contents of which are incorporated herein by reference.

### TECHNICAL FIELD

The present invention relates to the field of semiconductor devices, in particular to a device module embedded with switch chip and a manufacturing method of the device module.

### BACKGROUND

With the development of electronic products in the direction of light weight and miniaturization, a large number of devices are integrated on a single circuit board in more and more electronic products. For example, a frequency converter or a power supply circuit is usually provided with a switch chip such as IGBT (insulated gate bipolar transistor), field effect transistor (MOS transistor), thyristor, GTO (gate turn-off thyristor), GTR (giant transistor), BJT (bipolar junction transistor) or UJT (unijunction transistor), and the like, and the switch chip such as IGBT is often subjected to a relatively larger current.

In addition, the existing circuit boards are usually provided with energy storage devices such as capacitor, inductor etc. for storing the external electric energy and performing filtering etc. In general, the energy storage devices such as capacitors or inductors need to apply voltages to switch chip i.e. IGBT or MOS transistor etc.

As shown in FIG. 1, since the number of devices on the circuit board are usually small, all devices are typically integrated on the same surface of the circuit board, for example, MOS transistor 11 and capacitor 17 are provided on the upper surface of circuit board 10. Generally, MOS transistor 11 is provided with a plurality of pins 12, and circuit board 10 is provided with a plurality of pads 13, each pin 12 of MOS transistor 11 is soldered to pads 13 by solder 14. Additionally, each pad 13 is connected to the wirings on the circuit board 10.

Similarly, capacitor 17 is also provided with two pins 18, and circuit board 10 is provided with pads 16 corresponding to the two pins 18. Each pin 18 is soldered to a pad 16 by solder 19. Additionally, pads 16 are also connected to the wirings on the circuit board 10. By doing so, MOS transistor 11 is electrically connected to capacitor 17 via wirings on the circuit board 10.

However, since MOS transistor 11 and capacitor 17 are disposed on the same surface of circuit board 10 and capacitor 17 may merely be disposed at one side of the MOS transistor 11, while MOS transistor 11 and capacitor 17 has large volume, a wiring with long distance between MOS transistor 11 and capacitor 17 will be required. With the increase of wiring length between the capacitor 17 and MOS transistor 11, the loss on the wiring increases during the electric energy transmission. In order to ensure that the voltage applied to MOS transistor 11 is large enough, generally, the energy storage capacity of capacitor 17 needs to be improved, for example, using a bulky capacitor capable of storing more energy.

However, MOS transistor 11 is a switch chip which is always in a high-frequency switching state when the circuit works, namely, switching on and off, repeatedly. The high-frequency switching will cause devices such as capacitor or inductor etc. to produce high-frequency oscillation signals such as high-frequency harmonic signals which will cause electromagnetic interference to surrounding devices, for example, interference will be caused to the controller thereby affecting the operations of the controller.

For this reason, designers usually design a large number of anti-electromagnetic-interference circuits on the circuit board in the circuit design, for example, a shielding layer is configured to protect devices which are susceptible to electromagnetic interference, or a circuit is configured to lead high-frequency harmonics away. However, such designs would greatly increase the number of devices on the circuit board, and the area of the circuit board, such that the demands of miniaturized and light-weight electronic products of people cannot be satisfied. On the other hand, such designs would also increase the production cost of electronic products.

### SUMMARY

The first objective of the present invention is to provide a device module embedded with switch chip so as to enable effectively reducing high-frequency harmonic signals.

The second objective of the present invention is to provide a method for manufacturing a device module embedded with switch chip and enable the reduction of electromagnetic interference.

To achieve the first objective mentioned above, the device module embedded with switch chip provided by the present invention includes:

a double-sided circuit board, wherein a first surface of the double-sided circuit board is provided with a first pad, a second surface opposite to the first surface is provided with a second pad, and the first pad is electrically connected to the second pad by an electric-conductive via hole;

a heat dissipation substrate arranged at a side of the first surface of the double-sided circuit board, wherein the heat dissipation substrate includes an organic insulating base material, an electrical insulating heat dissipation body embedded in the organic insulating base material, and a metal layer formed on a surface of an outer side of the heat dissipation substrate, the metal layer is thermally connected to the electrical insulating heat dissipation body;

a switch chip embedded in the organic insulating base material, wherein pins of the switch chip are soldered to the first pad, and the other side of the switch chip opposite to the side with the pins is thermally connected to the electrical insulating heat dissipation body;

an energy storage device, wherein pins of the energy storage device are soldered to the second pad, according to a preferred embodiment of the present invention, the second pad at least partially overlaps with the first pad in a thickness direction of the double-sided circuit board, so as to shorten a distance of a conductive line between the first pad and the second pad.

More preferably, an axis of the electric-conductive via hole is perpendicular to a surface of the first pad. The axis of the electric-conductive via perpendicular to the surface of the first pad allows both the electric-conductive via and an electric-conductive material filled in the electric-conductive via hole to have a shortest length, so that the switch chip and the energy storage device can be designed with shortest distance.

According to another preferred embodiment of the present invention, the electrical insulating heat dissipation body includes a ceramic core and heat dissipation metal layers located on both sides of the ceramic core in the thickness direction of the double-sided circuit board. More preferably, the ceramic core is a silicon nitride ceramic or an alumina ceramic or an aluminum nitride ceramic. Preferably, the ceramic core is silicon nitride ceramic which can undergo rapid heating and cooling cycles, without cracking, under the condition of large temperature difference, thereby having excellent thermal stability.

In the present invention, the switch chip can be any switch device in discrete form, such as IGBT chip, MOS transistor chip, IGBT (insulated gate bipolar transistor), MOSFET (metal-oxide semiconductor field effect transistor), thyristor, GTO (gate turn-off thyristor), GTR (giant transistor), BJT (bipolar junction transistor), or UJT (unjunction transistor), and the like.

According to another embodiment of the present invention, the energy storage device is capacitor or inductor. In the present invention, preferably, the thickness of the double-sided circuit board is less than 1 mm. More preferably, the thickness of the double-sided circuit board is less than 0.8 mm. Further, preferably, the thickness of the double-sided circuit board is less than 0.6 mm. Yet, more preferably, the thickness of the double-sided circuit board is less than 0.5 mm. The thinner the thickness of the double-sided circuit board, the shorter is the length of the electric-conductive line between the switch chip and the energy storage device, so that the electromagnetic interference caused by the energy storage device can be effectively reduced.

To achieve the second objective mentioned above, the manufacturing method of the device module provided by the present invention includes: providing a double-sided circuit board with a first surface provided with a first pad and a second surface opposite to the first surface provided with a second pad, wherein the first pad and the second pad are electrically connected through an electric-conductive via hole; soldering pins of a switch chip to the first pad and soldering an electric insulating heat dissipation body at a side of the switch chip opposite to a side of the pins, wherein, the electric insulating heat dissipation body includes a ceramic core and heat dissipation metal layers located on both sides of the ceramic core in a thickness direction of the double-sided circuit board; sequentially layering an organic insulating base material having a through window and a base metal layer disposed on the organic insulating base material on the double-sided circuit board, wherein the organic insulating base material includes alternately disposed prepregs and organic insulating medium layers, the switch chip and the electric insulating heat dissipation body are embedded in the through window; hot-pressing the device module after the organic insulating base material is layered; forming a copper-clad layer on a surface of the device module away from the double-sided circuit board by sequentially using a chemical plating process and an electroplating process; and soldering pins of the energy storage device to the second pad.

In the above method, preferably, the second pad at least partially overlaps with the first pad in the thickness direction of the double-sided circuit board.

In the above method, preferably, the ceramic core is silicon nitride ceramic, alumina ceramic, or aluminum nitride ceramic.

In the module embedded with switch chip provided by the present invention, the switch chip and the energy storage devices such as capacitors are arranged on two opposite surfaces of the double-sided circuit board, and the switch chip and the energy storage devices are electrically connected by the electric-conductive via holes penetrating through the double-sided circuit board, therefore, the length of the connecting line between the switch chip and the energy storage devices is very short, and the length of the connecting line can be regarded as the distance between the first pad and the second pad.

Since the distance between the first pad and the second pad is the thickness of the double-sided circuit board, generally, the thickness of the double-sided circuit board is less than 1 mm, by doing so, the wiring from the energy storage device to the switch chip has short distance, less electric energy is consumed in the lines, and the energy storage device with small electric storage capacity can also meet the working requirement of the circuits. Therefore, the invention can realize energy storage by using small capacitors or small inductors. For devices with small power storage capability, even if the switch chip works at high frequency, the high-order harmonic signals produced by the energy storage devices are very weak, and the electromagnetic interference with the surrounding devices and the influence on parasitic elements (i.e. resistance and capacitance) is very weak, so, basically, there is no impact on the normal work of the surrounding devices.

Further, the volume of the energy storage devices can be reduced by using small capacitors or small inductors, thereby reducing the area required for the circuit board and ultimately, the volume of the electronic product is reduced. Moreover, since there is no need to dispose a large number of shielding layers or circuits for leading the high-order harmonic signals away on the double-sided circuit board, the production cost of the device module can be reduced.

Additionally, since the switch chip and the electric insulating heat dissipation body are internally disposed in the heat dissipation substrate, simultaneously and a high heat conductive channel of the electric insulating heat dissipation body is formed in the thickness direction of the heat dissipation substrate, the heat generated by the switch chip can be led away in time, thereby avoiding the impacts of an accumulation of the heat generated during the operation of the switch chip.

### BRIEF DESCRIPTION OF THE DRAWINGS

FIG. 1 is a structural schematic diagram of a conventional module having switch device.

FIG. 2 is an electrical schematic diagram of the circuits applied to the embodiment of the device module embedded with switch chip according to the present invention;

FIG. 3 is a structural schematic diagram of the embodiment of the device module embedded with switch chip according to the present invention;

FIG. 4 is a structural schematic diagram of the first stage of the embodiment of the manufacturing method of the device module embedded with switch chip according to the present invention;

FIG. 5 is a structural schematic diagram of the second stage of the embodiment of the manufacturing method of the device module embedded with switch chip according to the present invention;

FIG. 6 is a structural schematic diagram of the third stage of the embodiment of the manufacturing method of the device module embedded with switch chip according to the present invention;

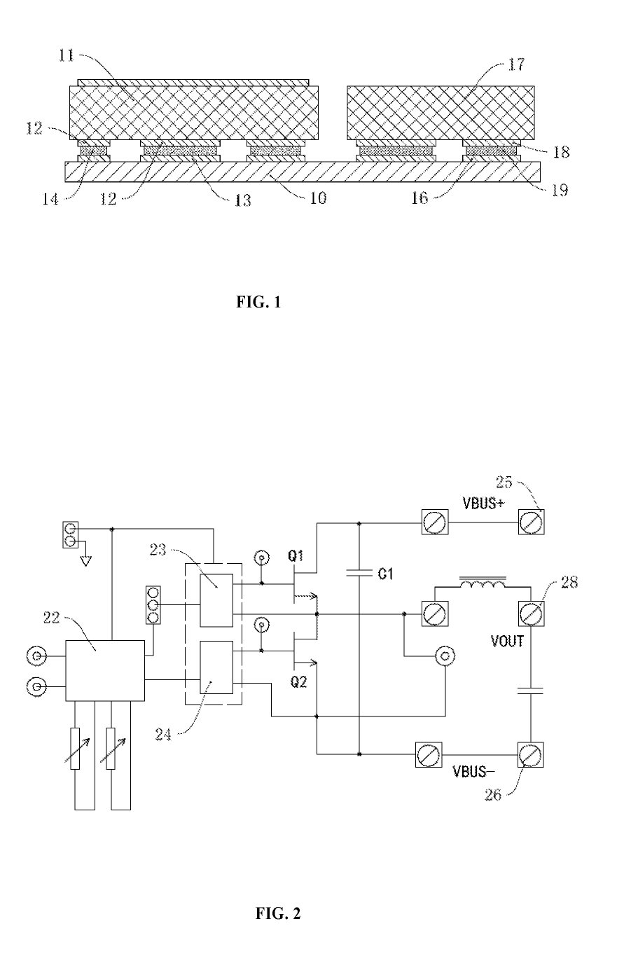

The present invention will be described in detail with reference to the drawings and embodiments, hereinafter.

### DETAILED DESCRIPTION OF THE EMBODIMENTS

Embodiment of the device module embedded with switch chip: in the embodiment, the device module embedded with a switch chip can be applied to the power supply circuit. Referring to FIG. 2, the circuit where the device module of the present embodiment is applied is a power supply circuit, for example, a power supply circuit having a rectifier circuit. In the embodiment, the power supply circuit includes terminals 25, 26 for receiving an external alternating current power supply and converting the external alternating current power source into a direct current power source to output. Therefore, the rectifier circuit is provided with two switch chips Q1 and Q2. In this embodiment, the switch chips may be chips having switching performance such as triodes, field effect transistors (MOS transistors), or IGBT.

In order to control the on-off of the switch chips Q1 and Q2, the power supply circuit is provided with control chip 22 and two drive chips 23 and 24. The control chip 22 is configured for sending drive signals to drive chips 23 and 24, and drive chip 23 is configured for controlling the on-off of the switch chip Q1. For example, when drive chip 23 outputs a high-level signal to switch chip Q1, switch chip Q1 is turned on, and when drive chip 23 outputs a low-level signal to switch chip Q1, switch chip Q1 is turned off. Similarly, when drive chip 24 outputs a high-level signal to switch chip Q2, switch chip Q2 is turned on, and when drive chip 24 outputs a low-level signal to switch chip Q2, switch chip Q2 is turned off.

Additionally, the power supply circuit is further provided with energy storage device, such as capacitor C1 shown in FIG. 2. Both ends of capacitor C1 are respectively connected to the drain terminal of switch chip Q1 and the source terminal of switch chip Q2, so that capacitor C1 is directly connected to switch chips Q1 and Q2 on the circuit board. By doing so, a circuit design convenient for reducing the distance between switch chips Q1, Q2 and capacitor C1 is provided.

The externally input alternating current is rectified by a half-bridge rectifier circuit composed of switch chips Q1 and Q2 to form a direct current output, and the direct current is output to the outside through the terminal 28.

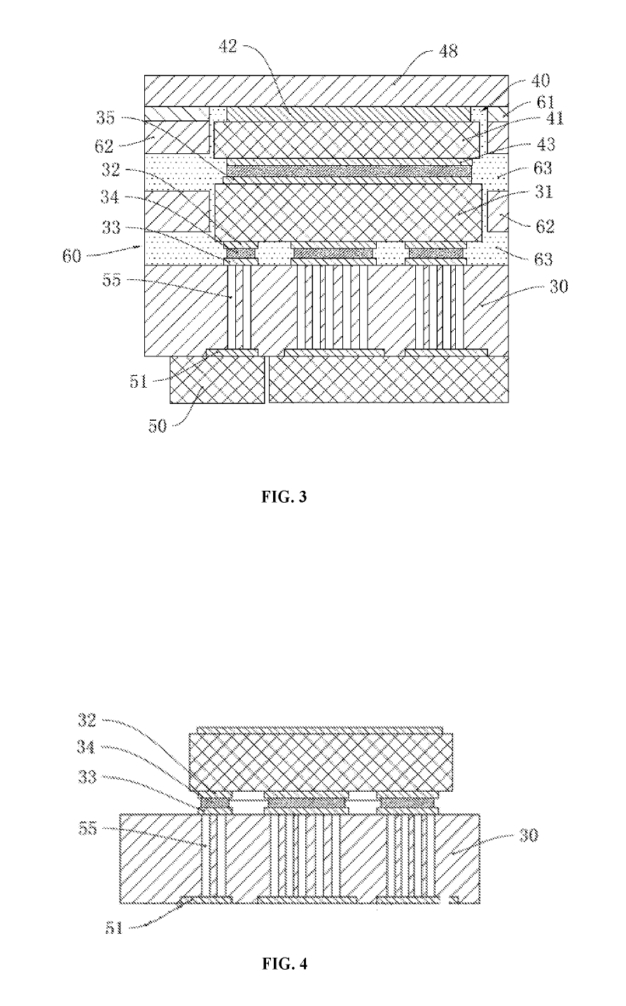

The structure of the device module according to the present embodiment will be described with reference to FIG. 3 hereinafter. The device module according to the present embodiment includes double-sided circuit board 30. The thickness of double-sided circuit board 30 is less than 1 mm, for example, 0.4 mm. Double-sided circuit board 30 may be a flexible circuit board such as a polyimide circuit board, or a rigid circuit board such as a FR4 circuit board. In other embodiments of the present invention, the thickness of double-sided circuit board 30 may be greater than 1 mm, for example, 2 mm.

The upper surface of double-sided circuit board 30 is provided with switch chip 31, and the lower surface of double-sided circuit board 30 is provided with capacitor 50 on. Referring to FIG. 3, switch chip 31 and capacitor 50 are disposed on two opposite surfaces of the double-sided circuit board 30, respectively. It should be noted that the directions “upper” and “lower” in the present invention refer to the directions shown in FIG. 3 which should not be construed as limits of the present invention.

The upper surface of the double-sided circuit board 30 is provided with a plurality of pads 33. A side of switch chip 31 close to the double-sided circuit board 30 is provided with a plurality of pins 32. Each of the pins 32 is soldered to pads 33 by soldering materials 34. Typically, pads 33 are formed by etching copper foil, and soldering materials 34 may be electric-conductive materials such as silver paste, copper paste, tin paste, or the like. Preferably, the area of pads 33 is slightly larger than the area of pins 32 so that pins 32 can fully contact pads 33. The lower surface of double-sided circuit board 30 is also provided with a plurality of pads 51. The pins of capacitor 50 are soldered to pads 51.

In order to realize the electrical connection between switch chip 31 and capacitor 50, in the present embodiment, double-sided circuit board 30 is provided with a plurality of electric-conductive via holes 55, and each electric-conductive via hole 55 penetrates through the upper and lower surfaces of double-sided circuit board 30. Referring to FIG. 3, the upper ends of electric-conductive via holes 55 are connected to pads 33, and the lower ends of electric-conductive via holes 55 are connected to pads 51. The inner wall of electric-conductive via hole 55 is configured with an electroplated copper layer, so as to realize an electrical connection between pads 33 and pads 51. It can be noted that in the present embodiment, pins 32 of switch chip 31 and the pins of capacitor 50 are electrically connected to each other through pads 33, electric-conductive via holes 55, and pads 51.

Specifically, when double-sided circuit board 30 is manufactured, double-sided circuit board 30 may be first drilled, for example, laser drilling is used to form a through hole, then a layer of electric-conductive material like metal materials such as copper etc. is electroplated on the inner wall of the through hole, and finally, insulating material such as insulating resin is filled in the through hole plated with the electric-conductive material to form electric-conductive via hole 55.

The electric energy output by capacitor 50 would be conducted to switch chip 31 through pads 51, electric-conductive via holes 55 and pads 33, since the area and the thickness of pads 51 and pads 33 are difficult to change, in order to obtain a shorter wiring between switch chip 31 and capacitor 50, in the present embodiment, electric-conductive via holes 55 with shortest length are configured so as to reduce the wiring length between switch chip 31 and capacitor 50, thereby reducing the consumption of the electric energy output by the capacitor 50 in the line.

In order to set the wiring between switch chip 31 and capacitor 50 with the shortest distance, on the one hand, switch chip 31 and capacitor 50 are set sufficiently close to each other. Referring to FIG. 3, switch chip 31 and capacitor 50 are located at the upper and lower sides of the double-sided circuit board 30 at opposite positions, namely, in the thickness direction of the double-sided circuit board 30, the switch chip 31 and the capacitor 50 are at least partially overlapped.

Also, for pads 33 and pads 51 connected by the same electric-conductive via holes 55, the projection patterns of pads 51 and pads 31 are also at least partially overlapped in the projection direction of pads 33. Preferably, if the areas of pads 33 and pads 51 are the same, the projection patterns of pads 33 and pads 51 are completely overlapped, and if the area of one pad is larger than the area of another pad, the projection pattern of the pad having a smaller area is completely located within the projection pattern of the pad having a larger area.

Since the pads of switch chip 31 and the pads of capacitor 50 are disposed right opposite to each other on both surfaces of double-sided circuit board 30, the electric-conductive via holes 55 can be configured with the shortest length. Referring to FIG. 3, the axes of electric-conductive via holes 55 are perpendicular to the upper surfaces of pads 33, and since pads 33 and pads 51 are parallel to each other, actually, electric-conductive via holes 55 are perpendicular to pads 33 and pads 51.

Apparently, as shown in FIG. 3, a plurality of electric-conductive via holes 55 may be provided between pads 33 disposed below switch chip 31 and pads 51 disposed above capacitor 50, so that even if the electric-conductive material in a certain electric-conductive via hole 55 is abnormal, the conductivity of the electric-conductive material in the other electric-conductive via holes 55 would not be affected. Also, the plurality of electric-conductive via holes 55 are parallel to each other, namely, the axis of each electric-conductive via hole 55 is perpendicular to the surface of pad 33.

Apparently, in practical application, pads 33 and pads 51 may not be right opposite to each other. Preferably, in view of the projection of pads 33, it is acceptable that merely the projection patterns of pads 33 at least partially overlap with the projection patterns of pads 51. Also, the axes of electric-conductive via holes 55 may not perpendicular to surfaces of pads 33, the axes of electric-conductive via holes 55 may be configured as inclined. For example, an angle of 80° is formed between the axis of electric-conductive via hole 55 and the surface of pad 33, in this way the objective of the present invention can also be achieved.

Since switch chip 31 performs the on-off operation at a high frequency, a large amount of heat is generated when switch chip 31 operates. In order to prevent the heat generated by switch chip 31 from affecting the operation of switch chip 31, the heat of switch chip 31 needs to be timely led away. In the present embodiment, switch chip 31 is internally embedded within a heat dissipation substrate. Specifically, the heat dissipation substrate includes organic insulating base materials 60, electric insulating heat dissipation body 40 internally embedded within organic insulating base materials 60, and metal layer (copper-clad layer) 48 formed on an outer surface of the heat dissipation substrate and thermally connected to electric insulating heat dissipation body 40. Organic insulating base materials 60 includes a plurality layers of prepregs 63 and organic insulating medium layers 62 such as FR4 or BT. Prepregs 63 and organic insulating medium layers 62 are alternately disposed.

Electric insulation heat dissipation body 40 includes ceramic core 41 and heat dissipation metal layers 42, 43 located at both sides of ceramic core 41. Moreover, one heat dissipation metal layer 43 close to the switch chip 31 is soldered to a side of the switch chip 31 opposite to the side of pins 32. By doing so, the heat generated by the switch chip 31 can be rapidly conducted into the electric insulation heat dissipation body 40 and further conducted into the metal layers (copper-clad layers) 48 to be rapidly emitted. Preferably, ceramic core 41 is silicon nitride, alumina, or aluminum nitride ceramic. Most preferably, ceramic core 41 is made of silicon nitride. Since the silicon nitride has the advantage of being not prone to cracking under heating and cooling cycles, in the case where a large amount of heat is generated during the operation of switch device 31 such as IGBT or MOS transistor etc., the silicon nitride is also not prone to cracks. Copper-clad layer 48 may be in contact with an external heat dissipation body, for example, copper-clad layer 48 may be soldered to an external aluminum radiator to rapidly dissipate heat from switch chip 31.

Embodiment of the manufacturing method of the device module embedded with switch chip:

The manufacturing method of the device module will be described with reference to FIGS. 4-6 hereinafter. First, a double-sided circuit board is manufactured. As shown in FIG. 4, double-sided circuit board 30 may be manufactured by using a glass-fiber epoxy-resin double-sided copper-clad plate, a polyimide double-sided copper-clad plate, or a polyester-film double-sided copper-clad plate. Specifically, the double-sided copper-clad plate is drilled with holes. For example, a plurality of through holes penetrating the double-sided copper-clad plate are formed in way of laser drilling, and then electric-conductive materials are configured within the through holes to form electric-conductive via holes. The configuration of electric-conductive materials may be filling the electric-conductive material into the via hole or plating a layer of electric-conductive metal on the via hole before filling the insulating material.

Wiring patterns and pads are respectively formed on two opposite surfaces of double-sided circuit board 30, for example, a plurality of first pads 33 are formed on the first surface and a plurality of pads 51 are formed on the second surface. Apparently, the first pads 33 for soldering switch chip 31 are preferably disposed directly above the pads 51 for soldering capacitor 50, and first pads 33 are electrically connected to second pads 51 through electric-conductive via holes 55. Preferably, the axis of electric-conductive via hole 55 is perpendicular to the surface of first pad 33, so that the electric-conductive via hole 55 has the shortest length equal to the thickness of the double-sided circuit board 30, for example one or two millimeters or even less than one millimeter.

Preferably, the first pads 33 and the second pads 51 should be disposed directly opposite to each other during the arrangement of the first pads 33 and the second pads 51, namely, in the projection direction of the first pads 33 (i.e., in the thickness direction of the double-sided circuit board 30), the projection patterns of the second pads 51 at least partially overlap with the first pads 33, so as to ensure that electric-conductive via holes 55 have the shortest length.

Subsequently, first pad 33 is soldered with switch chip 31 such as IGBT or MOS transistor. As shown in FIG. 5, the electric insulation heat dissipation body 40 is soldered above the switch chip 31 while the switch chip 31 is soldered or after the soldering of the switch chip 31 is completed, that is to say the electric insulation heat dissipation body 40 is soldered at a side of the switch chip 31 away from the double-sided circuit board 30. In the present embodiment, the electric insulation heat dissipation body 40 includes ceramic core 41 and heat dissipation metal layers 42 and 43 located on both sides of the ceramic core 41 in the thickness direction of the double-sided circuit board 30. Preferably, ceramic core 41 is a silicon nitride, alumina, or aluminum nitride ceramic. Most preferably, the ceramic core 41 is made of silicon nitride.

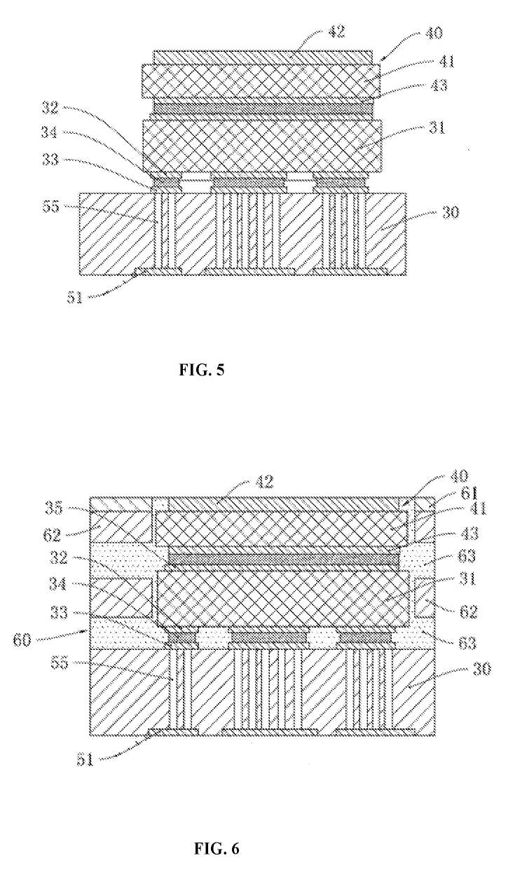

As shown in FIG. 6, organic insulating base material 60 having through windows and base metal layer 61 disposed on the organic insulating base material 60 are layered on the double-sided circuit board 30. The organic insulating base material 60 include prepregs 63 and organic insulating medium layers 62 which are sequentially and alternately disposed. Switch chip 31 and electric insulating heat dissipation body 40 are embedded in through windows of the organic insulating base material 60. Moreover, outermost organic insulating medium layer 62 and base metal layer 61 are provided in the form of copper-clad plate.

Subsequently, the power module, after the organic insulating base material 60 is layered, is subjected to hot pressing. During the hot pressing process, the prepregs 63 flow to fill the gaps of the through windows for curing and connecting double-sided circuit board 30 and the heat dissipation substrate. Moreover, the step of removing the resins flowing to the surfaces of heat dissipation metal layer 42 and base metal layer 61 (e.g., mechanically grinding) during the hot pressing which may be included is controlled according to the hot pressing process.

After that, again, referring to FIG. 3, copper-clad layer 48 is formed on the outer surface of the heat dissipation substrate away from double-sided circuit board 30. The copper-clad layer 48 includes a bottom copper layer formed by electroless plating process and an electroplated thickening copper layer formed by electroplating process.

Finally, the capacitor 50 is soldered on the second pad 51. Since in the present invention, the switch chip and the capacitor are respectively configured on two opposite surfaces of the double-sided circuit board, and the pads on the two surfaces are connected through the electric-conductive via holes, the wiring between the switch chip and the capacitor is very short which equals to the length of the electric-conductive via hole. If the thickness of the double-sided circuit board is small, the wiring between the switch chip and the capacitor is usually one or two millimeters, or even less than one millimeter, so that the capacitor with small power storage capacity would meet the requirement of use. With the use of capacitor with very small storage capacity, high-order harmonic generated by the capacitor would be effectively reduced, thereby reducing the phenomenon of electromagnetic interference.

In addition, it should also be noted that the energy storage device disposed below the double-sided circuit board may not be a capacitor, the energy storage device may also be an inductor which does not affect the implementation of the present invention. In addition, the device module of the present invention is not limited to being applied to a power supply circuit, as long as the module is configured with switch chip and energy storage device, the solutions of the present invention can be used.

Although the present invention has been described above according to the preferred embodiments, it should be understood that the equivalent improvements performed by those skilled in the art without departing from the scope of the present invention should fall within the scope of the present invention. For example, changes made in the specific materials of the ceramic heat dissipation body and the shapes of the cross-section of the via holes, etc.

What is claimed is:

1. A device module embedded with a switch chip, comprising:
a double-sided circuit board, wherein a first surface of the double-sided circuit board is provided with a first pad, and a second surface of the double-sided circuit board opposite to the first surface is provided with a second pad; the first pad and the second pad are electrically connected by an electric-conductive via hole;
a heat dissipation substrate arranged on a side of the first surface of the double-sided circuit board, wherein the heat dissipation substrate comprises an organic insulating base material, an electric insulating heat dissipation body embedded in the organic insulating base material, and a metal layer formed on an outer surface of the heat dissipation substrate and thermally connected to the electric insulating heat dissipation body;
a switch chip embedded in the organic insulating base material, wherein a plurality of pins of the switch chip are soldered to the first pad, and a side of the switch chip opposite to a side of the plurality of pins is thermally connected to the electric insulating heat dissipation body; and
an energy storage device, wherein a plurality of pins of the energy storage device are soldered to the second pad.

2. The device module according to claim 1, wherein the second pad at least partially overlaps with the first pad in a thickness direction of the double-sided circuit board.

3. The device module according to claim 1, wherein the electric insulating heat dissipation body comprises a ceramic core and a plurality of heat dissipation metal layers located at both sides of the ceramic core in a thickness direction of the double-sided circuit board.

4. The device module according to claim 3, wherein the ceramic core is one item selected from the group consisting of silicon nitride ceramic, alumina ceramic, and aluminum nitride ceramic.

5. The device module according to claim 1, wherein the switch chip is one item selected from the group consisting of insulated gate bipolar transistor (IGBT), MOS transistor, thyristor, gate turn-off thyristor (GTO), giant transistor (GTR), bipolar junction transistor (BJT), and unijunction transistor (UJT).

6. The device module according claim 1, wherein the energy storage device is a capacitor or an inductor.

7. The device module according to claim 1, wherein a thickness of the double-sided circuit board is less than 1 mm.

8. A method for manufacturing a device module embedded with switch chip, comprising:
providing a double-sided circuit board, wherein a first surface of the double-sided circuit board is provided with a first pad, a second surface opposite to the first surface is provided with a second pad, the first pad and the second pad are electrically connected by an electric-conductive via hole, a plurality of pins of a switch chip are soldered to the first pad, and an electric insulating heat dissipation body is soldered to a side of the switch chip opposite to a side of the plurality of pins; wherein the electric insulating heat dissipation body comprises a ceramic core and a plurality of heat dissipation metal layers located at both sides of the ceramic core in a thickness direction of the double-sided circuit board;
sequentially layering an organic insulating base material having a through window and a base metal layer disposed on the organic insulating base material on the double-sided circuit board, wherein the organic insulating base material comprises alternately disposed prepregs and organic insulating medium layers, and the switch chip and the electric insulating heat dissipation body are embedded in the through window;
hot-pressing the device module after the device module is layered with the organic insulating base material;
forming a copper-clad layer on a surface of the device module away from the double-sided circuit board by using a chemical plating process and an electroplating process; and
soldering a plurality of pins of the energy storage device to the second pad.

9. The manufacturing method according to claim 8, wherein the second pad at least partially overlaps with the first pad in a thickness direction of the double-sided circuit board.

10. The manufacturing method according to claim 8, wherein the ceramic is one item selected from the group consisting of silicon nitride ceramic, alumina ceramic, and aluminum nitride ceramic.
